(19) United States
(12) Patent Application Publication
(10) Pub. No.: US 2025/0054903 A1
(43) Pub. Date: Feb. 13, 2025

(54) MICRO BONDING DEVICE, BONDING BACKPLANE AND DISPLAY DEVICE

(71) Applicant: Xiamen Extremely PQ Display Technology Co., Ltd., Xiamen (CN)

(72) Inventor: GANG MA, Xiamen (CN)

(21) Appl. No.: 18/932,568

(22) Filed: Oct. 30, 2024

Related U.S. Application Data
(63) Continuation of application No. PCT/CN2022/133769, filed on Nov. 23, 2022.

(30) Foreign Application Priority Data
Aug. 28, 2024 (CN) 2024221025968

(51) Int. Cl. H01L 23/00; H01L 25/075; H01L 33/00

(52) U.S. Cl. CPC H01L 24/66; H01L 24/69; H01L 25/0753; H01L 33/005; H01L 2224/66; H01L 2224/69; H01L 2924/12041

(57) ABSTRACT

A micro bonding device, a bonding backplane and a display device are provided. The micro bonding device is configured to bond and connect two to-be-bonded electrodes, the micro bonding device includes a main part and multiple micro connectors protruding from the main part; the multiple micro connectors are arranged at intervals, and are configured to plugged with the two to-be-bonded electrodes. The micro bonding device, the bonding backplane and the display device can reduce repair difficulty of the micro electronic device, and prevent impact on surrounding already welded chips during repair.

### CROSS-REFERENCE TO RELATED APPLICATIONS

This application is a continuation-in-part of International Application No. PCT/CN2022/133769, filed on Nov. 23, 2022, which is herein incorporated by reference in its entirety. This application also claims priority to Chinese Patent Application No. 202422102596.8, filed Aug. 28, 2024, which is herein incorporated by reference in its entirety.

### TECHNICAL FIELD

The disclosure relates to the technical field of electronic devices, and more particularly to a micro bonding device, a bonding backplane and a display device.

### BACKGROUND

Micro light emitting diode (LED) display technology is widely used in various display devices at present. A micro LED display backplane requires mass transfer and bonding of micro LED chips. A post-bonding repair technology is a key to achieving mass production. The repair method in the related art is generally to use laser to remove a chip at a bad point position, then a bonding adhesive or solder material is added to the original position (i.e., the bad point position) or a position of a spare electrode by dispensing or inkjet printing, and another chip is added to the original position (i.e., the bad point position) or the position of the spare electrode. Finally, a repair core is bonded to the backplane by a heating welding method. As a resolution of the micro LED display panel becomes higher and higher, a size of the chip becomes smaller and the gap between chips becomes smaller, it is becoming more and more difficult to use traditional processes for single-point repair. In addition, in this process, it is easy to affect quality of solder joints of the surrounding already welded chips. Therefore, the existing repair process has the problems of high repair difficulty and high repair cost.

### SUMMARY

It is urgent to provide a new solution to solve the aforementioned problem of difficulty in repair.

Therefore, in order to overcome at least part defects in the related art, embodiments of the disclosure provide a micro bonding device, a bonding backplane and a display device, which can reduce repair difficulty of a micro electronic device, prevent impact on surrounding already welded chips during repair.

On the one hand, an embodiment of the disclosure provides a micro bonding device, which is configured to bond and connect two to-be-bonded electrodes. The micro bonding device includes: a main part and multiple micro connectors. The multiple micro connectors protrude from the main part, and are arranged at intervals. The multiple micro connectors are configured to plug with the two to-be-bonded electrodes.

In an embodiment, the main part includes a first surface and a second surface, and the first surface and the second surface are opposite in a first direction. The multiple micro connectors include multiple first microneedles protruding from the first surface and multiple second microneedles protruding from the second surface. The multiple first microneedles are configured to plug with one of the two to-be-bonded electrodes, and the multiple second microneedles are configured to plug with the other of the two to-be-bonded electrodes.

In an embodiment, the main part defines a first height dimension along the first direction and a first width dimension along a second direction, and the second direction is perpendicular to the first direction. The first height dimension is in a range of 1 micron (μm) to 3 μm, and the first width dimension is in a range of 1 μm to 5 μm. Heights of the multiple first microneedles and the multiple second microneedles protruding from the main part are in a range of 100 nanometers (nm) to 1000 nm respectively. Each of the multiple first microneedles and each of the multiple second microneedles each define a second width dimension along the second direction, and the second width dimension is in a range of 100 nm to 1000 nm.

In an embodiment, the micro bonding device further includes: a first flying wing and a second flying wing. The first flying wing and the second flying wing are symmetrically disposed on two opposite sides of the main part in a second direction. The second direction is perpendicular to the first direction, and the first flying wing and the second flying wing individually extend along the first direction.

In an embodiment, the main part defines a first guide groove and a second guide groove. The first guide groove and the second guide groove are symmetrically disposed along a third direction, and the third direction is perpendicular to the first direction. The first guide groove and the second guide groove individually penetrate through the first surface and the second surface along the first direction.

In an embodiment, the main part includes a first surface, a second surface and a side surface. The first surface and the second surface are opposite in a first direction, and the side surface is located between the first surface and the second surface. The multiple micro connectors are multiple blades respectively protruding from the side surface and disposed around the main part, each of the multiple micro connectors includes a first connector end and a second connector end, and the first connector end and the second connector end are opposite in the first direction. The first connector end is configured to plug with one of the two to-be-bonded electrodes, and the second connector end is configured to plug with the other of the two to-be-bonded electrodes.

In an embodiment, the main part defines a third width dimension along the second direction, the second direction is perpendicular to the first direction, and the third width dimension is in a range of 100 nm to 1000 nm. A blade length of each of the multiple micro connectors protruding from the side surface is in a range of 1 μm to 2 μm.

In an embodiment, the main part defines a through hole penetrating from the first surface to the second surface.

In an embodiment, the main part defines a third width dimension along a second direction, the second direction is perpendicular to the first direction, and the third width dimension is in a range of 1 μm to 3 μm. A blade length of each of the multiple micro connectors protruding from the side surface is in a range of 0.5 μm to 1 μm.

In an embodiment, each of the multiple micro connectors includes a blade middle located between the first connector end and the second connector end, and thicknesses of the first connector end and the second connector end each are smaller than or equal to a thickness of the blade middle.

In the other hand, an embodiment of the disclosure provides a bonding backplane, including: a substrate, a micro electronic device and the micro bonding device according to any one of the foregoing. The substrate includes a first to-be-bonded electrode. The micro electronic device includes a second to-be-bonded electrode. The micro bonding device is disposed between the first to-be-bonded electrode and the second to-be-bonded electrode. At least part of the multiple micro connectors are plugged into the first to-be-bonded electrode, and at least part of the multiple micro connectors are plugged into the second to-be-bonded electrode.

In an embodiment, hardness of the multiple micro connectors is greater than hardness of the first to-be-bonded electrode and hardness of the second to-be-bonded electrode.

In an embodiment, the micro electronic device includes a device body and the second to-be-bonded electrode. The device body has a bottom surface, a top surface and a chip side surface. The bottom surface and the top surface are opposite in a stacking direction, and the chip side surface is adjacent to the bottom surface and the top surface. The device body includes multiple semiconductor layers stacked along the stacking direction. The second to-be-bonded electrode is electrically connected to the device body, and is partially disposed on the chip side surface of the device body.

In an embodiment, the second to-be-bonded electrode includes a chip electrode side disposed on the chip side surface. The micro bonding device is plugged with an end of the chip electrode side and the first to-be-bonded electrode individually.

In an embodiment, the second to-be-bonded electrode includes a chip electrode side and a chip electrode bottom. The chip electrode side is disposed on the chip side surface, and the chip electrode bottom is disposed on the bottom surface, and is connected to the chip electrode side. The micro bonding device is plugged with the chip electrode bottom and the first to-be-bonded electrode individually.

In an embodiment, the second to-be-bonded electrode includes a chip electrode side and a chip electrode top. The chip electrode side is disposed on the chip side surface, and the chip electrode top is disposed on the top surface. The multiple semiconductor layers include a first semiconductor layer and a second semiconductor layer. The second semiconductor layer is disposed between the first semiconductor layer and the top surface, and the chip electrode top is electrically connected to the second semiconductor layer, and is insulated from the first semiconductor layer. The second to-be-bonded electrode further includes a chip electrode bottom, and the chip electrode bottom is connected to an end of the chip electrode side facing away from the chip electrode top. The micro bonding device is plugged with the chip electrode bottom and the first to-be-bonded electrode individually.

In an embodiment, the substrate defines a groove. The first to-be-bonded electrode includes a substrate electrode bottom, and the substrate electrode bottom is disposed on a bottom of the groove. The micro electronic device is disposed in the groove. The micro bonding device is plugged with the second to-be-bonded electrode and the substrate electrode bottom individually.

In an embodiment, the first to-be-bonded electrode further includes a substrate electrode side, and the substrate electrode side is disposed on a side wall of the groove, and is connected to the substrate electrode bottom. The second to-be-bonded electrode includes a chip electrode side, and the chip electrode side is disposed on the chip side surface, and is connected to the substrate electrode side.

In an embodiment, the first to-be-bonded electrode includes a substrate electrode bottom and a substrate electrode side. The substrate electrode bottom is disposed on the substrate, and the substrate electrode side extends along the substrate electrode bottom in a direction facing away from the substrate. The micro bonding device is plugged with the substrate electrode bottom and the second to-be-bonded electrode individually. The second to-be-bonded electrode includes a chip electrode side, and the chip electrode side is disposed on the chip side surface, and is connected to the substrate electrode side.

In an embodiment, a number of the second to-be-bonded electrodes is multiple, and a number of the first to-be-bonded electrodes is multiple, and the multiple second to-be-bonded electrodes of the micro electronic device correspond to the multiple first to-be-bonded electrodes one by one and are bonded to each other. The substrate electrode sides of the multiple first to-be-bonded electrodes of the micro electronic device enclosed together to define an accommodating groove, and the micro electronic device is disposed in the accommodating groove.

In an embodiment, the main part includes a first surface and a second surface, and the first surface and the second surface are opposite in the first direction. The multiple micro connectors include multiple first microneedles protruding from the first surface and multiple second microneedles protruding from the second surface. The multiple first microneedles are configured to plug with one of the two to-be-bonded electrodes, and the multiple second microneedles are configured to plug with the other of the two to-be-bonded electrodes.

In an embodiment, the multiple semiconductor layers include a first semiconductor layer, an active layer and a second semiconductor layer, and the first semiconductor layer has the bottom surface, the top surface and the chip side surface. The active layer covers the bottom surface and the chip side surface, and the second semiconductor layer covers the active layer.

In an embodiment, the device body further includes a passivation layer, and the passivation layer covers the second semiconductor layer. The second to-be-bonded electrode includes a first polar electrode and a second polar electrode. The second polar electrode penetrates through the passivation layer and is electrically connected to the second semiconductor layer. The first polar electrode is insulated from the second semiconductor layer by the passivation layer, and the first polar electrode is electrically connected to the first semiconductor layer. At least part of one of the first polar electrode and the second polar electrode is disposed on the chip side surface.

In an embodiment, the multiple semiconductor layers include a first semiconductor layer, an active layer and a second semiconductor layer, and the first semiconductor layer has the bottom surface, the top surface and the chip side surface. The active layer and the second semiconductor layer are stacked on the bottom surface in that order. Areas of orthographic projections of the active layer and the second semiconductor layer on the bottom surface are smaller than an area of the bottom surface. The second to-be-bonded electrode includes a first polar electrode and a second polar electrode. The second polar electrode is disposed on a side of the second semiconductor layer facing away from the active layer, and is electrically connected to the second semiconductor layer. At least part of the first polar electrode is disposed on the chip side surface and is electrically connected to first semiconductor layer.

In an embodiment, the device body further includes a passivation layer, and the passivation layer is disposed on the bottom surface. The first polar electrode includes a chip electrode side and a chip electrode bottom. The chip electrode side is disposed on the chip side surface, and the chip electrode bottom is disposed on a side of the passivation layer facing away from the bottom surface.

Still in the other hand, an embodiment of the disclosure provides a display device, including the bonding backplane according to any one of the foregoing, and the micro electronic device is a micro light emitting device.

The above embodiments of the disclosure have at least one of the following beneficial effects. The micro bonding device can be plugged with the two to-be-bonded electrodes by the multiple micro connectors arranged at intervals, so that the micro bonding device provided in the embodiment of the disclosure can be plugged with the electrodes of a micro LED chip and the corresponding electrodes on the substrate to achieve bonding when bonding the micro LED chip to the corresponding substrate. The setting of the multiple micro connectors makes it unnecessary to use the heating welding method during bonding, thus surrounding already welded chips will not be affected during the repair process. In addition, the micro bonding device provided in the embodiment of the disclosure can be used to bond by laser transfer, which is less difficult than the traditional inkjet printing or glue dispensing repair process.

### BRIEF DESCRIPTION OF DRAWINGS

Embodiments of the disclosure will be described in detail below in conjunction with drawings.

FIG. 1 illustrates a three-dimensional structural diagram of a micro bonding device according to an embodiment of the disclosure.

FIG. 2 illustrates a schematic diagram of a side surface of the micro bonding device of FIG. 1.

FIG. 3 illustrates a flowchart of a process for repairing the micro-bonding device according to an embodiment of the disclosure.

FIG. 4 illustrates a three-dimensional structural diagram of a micro bonding device according to an embodiment of the disclosure.

FIG. 5 illustrates a three-dimensional structural diagram of a micro bonding device according to an embodiment of the disclosure.

FIG. 6 illustrates a schematic structural diagram of a bonding backplane according to an embodiment of the disclosure.

FIG. 7 illustrates a schematic structural diagram of a bonding backplane according to an embodiment of the disclosure.

FIG. 8 illustrates a partial enlarged schematic diagram of an area A in FIG. 7.

FIG. 9 illustrates a schematic structural diagram of a bonding backplane according to an embodiment of the disclosure.

FIG. 10a illustrates a schematic structural diagram of a micro electronic device according to an embodiment of the disclosure.

FIG. 10b illustrates a schematic structural diagram of a micro electronic device according to an embodiment of the disclosure.

FIG. 10c illustrates a schematic structural diagram of a micro electronic device according to an embodiment of the disclosure.

FIG. 10d illustrates a schematic structural diagram of a micro electronic device according to an embodiment of the disclosure.

FIG. 11 illustrates a schematic structural diagram of a bonding backplane according to an embodiment of the disclosure.

FIG. 12 illustrates a schematic structural diagram of a bonding backplane according to an embodiment of the disclosure.

FIG. 13 illustrates a schematic structural diagram of a bonding backplane according to an embodiment of the disclosure.

FIG. 14 illustrates a schematic structural diagram of a substrate in the bonding backplane illustrated in FIG. 13.

FIG. 15 illustrates a schematic structural diagram of a display device according to an embodiment of the disclosure.

### LIST OF REFERENCE NUMBERS

10—micro bonding device; 11—main part; 111—first surface; 112—second surface; 113—first guide groove; 114—second guide groove; 115—side surface; 116—through hole; 12—micro connector; 121—first microneedle; 122—second microneedle; 123—first connector end; 124—second connector end; 125—blade middle; 131—first flying wing; 132—second flying wing; 20—substrate; 21—first to—be—bonded electrode; 211—substrate electrode bottom; 212—substrate electrode side; 22—groove; 23—accommodating groove; 24—driving circuit board; 25—pixel definition layer; 30—micro electronic device; 31—second to-be-bonded electrode; 31a—first polar electrode; 31b—second polar electrode; 311—chip electrode side; 312—chip electrode bottom; 313—chip electrode top; 32—device body; 321—bottom surface; 322—top surface; 323—chip side surface; 324—semiconductor layer; 3241—first semiconductor layer; 3242—second semiconductor layer; 3243—active layer; 325—passivation layer; 326—transparent electrode; 100—bonding backplane; 200—display device.

### DETAILED DESCRIPTION OF EMBODIMENTS

In order to make the above purposes, features and advantages of the disclosure more obvious and easy to understand, embodiments of the disclosure are described in detail below in conjunction with drawings.

In order to enable those skilled in the art to better understand technical solutions of the disclosure, the technical solutions in the embodiments of the disclosure will be clearly and completely described below in conjunction with the drawings in the embodiments of the disclosure. Apparently, the described embodiments are merely some of the embodiments of the disclosure, not all of the them. Based on the embodiments in the disclosure, all other embodiments obtained by those skilled in the art without creative work should fall within a scope of protection of the disclosure.

It should be noted that terms “first”, “second”, and the like in the specification and claims of the disclosure and the above drawings are used to distinguish similar objects, and are not necessarily used to describe a specific order or sequence. It should be understood that the terms used in this way can be interchangeable where appropriate, so that the embodiments of the disclosure described herein can be implemented in an order other than those illustrated or described herein. In addition, terms “including” and “having” and any of their variations are intended to cover non-exclusive inclusions, for example, processes, methods, systems, products or devices including a series of steps or units are not necessarily limited to those steps or units clearly listed, but may include other steps or units that are not clearly listed or inherent to these processes, methods, products or devices.

It should also be noted that division of multiple embodiments in the disclosure is only for convenience of description and should not constitute a special limitation. The features in various embodiments can be combined and referenced to each other without contradiction.

In the related art, a bonding repair process of a micro LED chip mainly includes the following steps: (1) an old chip in a to-be-repaired position is removed; (2) a bonding adhesive or solder material is added on a substrate electrode by using a glue dispensing process or an inkjet printing process; (3) a new chip is transferred to the to-be-repaired position; and (4) single-point heating bonding is performed on the to-be-repaired position. However, with the decrease of a size of the micro LED chip, sizes of the chip electrode and the substrate electrode also greatly decrease. The traditional glue dispensing process can no longer satisfy accuracy requirements. The traditional inkjet printing process has strict requirements on the selection of solder materials, thus it is difficult to achieve high-precision repair. In addition, the spacing between the micro LED chips is getting smaller and smaller, and the single-point heating bonding will also affect the chips that have been bonded at the adjacent positions. For this reason, the embodiments of the disclosure provide a new repair solution to solve at least part of the aforementioned defects.

### Embodiment 1

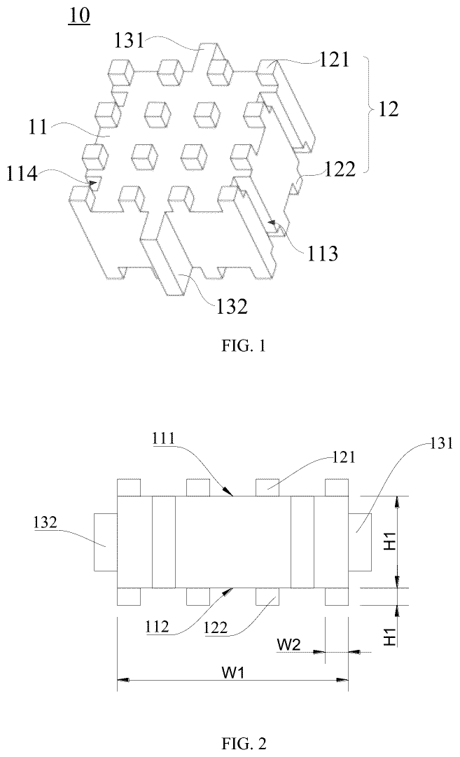

An embodiment 1 of the disclosure provides a micro bonding device 10, which is used to bond and connect two to-be-bonded electrodes. The micro bonding device 10 includes a main part 11 and multiple micro connectors 12. The multiple micro connectors 12 protrude from the main part 11, and are arranged at intervals. The multiple micro connectors 12 are configured to plug with the two to-be-bonded electrodes. Specifically, the two to-be-bonded electrodes can be a chip electrode of a micro LED chip and a substrate electrode on a display substrate corresponding to the chip electrode respectively. That is, the multiple micro connectors 12 are configured to plug with a chip electrode and a substrate electrode respectively, to achieve bonding between the micro LED chip and the substrate. Specifically, as shown in FIG. 1, in an embodiment, the main part 11 includes a first surface 111 and a second surface 112, and the first surface 111 and the second surface 112 are opposite in a first direction. The multiple micro connectors 12 include multiple first microneedles 121 and multiple second microneedles 122. The multiple first microneedles 121 protrude from the first surface 111, and the multiple second microneedles 122 protrude from the second surface 112. The multiple first microneedles 121 are configured to plug with one of the two to-be-bonded electrodes, and the multiple second microneedles 122 are configured to plug with the other of the two to-be-bonded electrodes. For example, when bonding the micro LED chip on the substrate, the multiple first microneedles 121 are plugged with the chip electrode, and the multiple second microneedles 122 are plugged with the substrate electrode. In this way, when repairing the micro LED chip, the physical plugging of the micro bonding device 10 with the chip electrode and the substrate electrode replaces the heating welding of the solder, and there is no need to heat the repair position separately, and it will not affect the adjacent soldered chips.

Specifically, a material of the micro bonding device 10 provided in the embodiment can be copper, nickel and another metal conductive material, and the micro bonding device 10 is in a form of a metal block as a whole. As shown in FIG. 1 and FIG. 2, the main part 11 defines a first height dimension H1 along the first direction and a first width dimension W1 along a second direction. The second direction is perpendicular to the first direction. The main part 11 is a cuboid structure. The first width dimension W1 is a length or a width of the first surface 111 (or the second surface 112), which is relative to dimensions of the two to-be-bonded electrodes. The first width dimension W1 is in a range of 1 μm to 5 μm. The first height dimension H1 is a height of the cuboid structure (i.e., the main part 11). The first height dimension H1 is in a range of 1 μm to 3 μm. Heights of the multiple first microneedles 121 and the multiple second microneedles 122 protruding from the main part 11 are in a range of 100 nm to 1000 nm. Each of the multiple first microneedles 121 and each of the multiple second microneedles 122 each defines a second width dimension W2 along the second direction, and the second width dimension W2 is in a range of 100 nm to 1000 nm. The multiple first microneedles 121 and the multiple second microneedles 122 each are a spiky structure, which can pierce into the two to-be-bonded electrodes to realize plug-in.

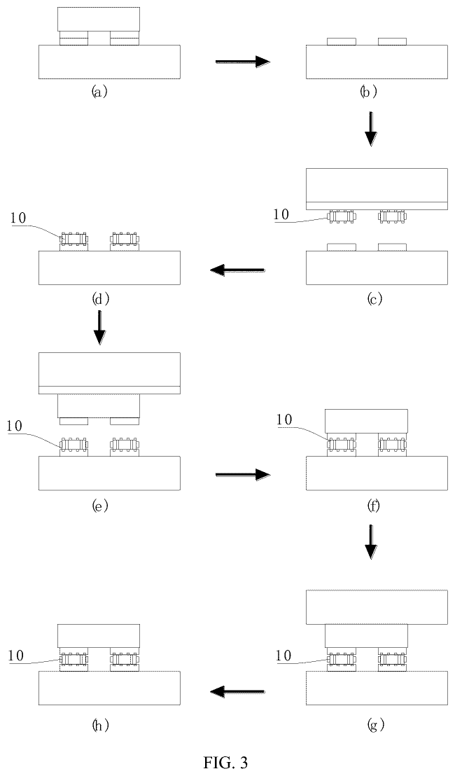

A principle of the micro bonding device 10 provided in the embodiment for use in the repair process is shown in steps (a) to (h) in FIG. 3. First, in the steps (a) to (b), an old chip on a to-be-repaired position of the substrate 20 is removed to expose a to-be-bonded electrode on the substrate 20. In the steps (c) to (d), the micro bonding device 10 is transferred to the substrate electrode. In this process, a laser-assisted transfer method is used to plug the micro bonding device 10 with the substrate electrode, and a transfer carrier is used to pick up the micro bonding device 10. After being irritated by the laser, an adhesive material on the transfer carrier is vaporized to release the micro bonding device 10 and provide a certain flying speed, so that the micro bonding device 10 is plugged with the substrate electrode. In the steps (e) to (f), a new chip is transferred onto the substrate 20, the laser-assisted transfer method is similarly used to provide a certain flying speed for the new chip, so that the chip electrode is plugged with the micro bonding device 10 on the substrate electrode. Finally, in the step (g), a pressing method is adopted to make the plugging of the micro bonding device 10 with the chip electrode and the substrate electrode more stable, to thereby obtain the repaired bonding structure in the step (h). The micro bonding device 10 provided in the embodiment can be applied to the laser-assisted transfer method in the transfer of the micro LED chips. Compared with the traditional repair solution using conductive glue or solder, it can use existing process equipment, the solution is simple and feasible, and the repair difficulty is reduced. Certainly, according to the above repair principle, the micro bonding device 10 provided in the embodiment can also be used for repair bonding in other micro device transfer processes similar to the micro LED chip.

In an embodiment, the micro bonding device 10 further includes a first flying wing 131 and a second flying wing 132. The first flying wing 131 and the second flying wing 132 are symmetrically disposed on two opposite sides of the main part 11 in the second direction. The second direction is perpendicular to the first direction, and the first flying wing 131 and the second flying wing 132 individually extend along the first direction. Referring to the orientation shown in FIG. 2, the first flying wing 131 and the second flying wing 132 are symmetrically disposed on left and right sides of the main part 11, and the first flying wing 131 and the second flying wing 132 extend along up and down directions respectively, to form a wing-liked structure. The first flying wing 131 and the second flying wing 132 play a role in aligning the flight path when the transfer carrier releases the micro bonding device 10 onto the target substrate (i.e., a process of the steps (c) to (d)). In an embodiment, the main part 11 defines a first guide groove 113 and a second guide groove 114. The first guide groove 113 and the second guide groove 114 are symmetrically disposed along a third direction, and the third direction is perpendicular to the first direction. The first guide groove 113 and the second guide groove 114 individually penetrate through the first surface 111 and the second surface 112 along the first direction, to further aligning the flight path. Specifically, the third direction can be the same as or different from the second direction. For example, referring to the orientation shown in FIG. 1, the first flying wing 131 and the second flying wing 132 are symmetrical in a front-rear direction, and the first guide groove 113 and the second guide groove 114 are symmetrical in a left-right direction. In this case, the second direction and the third direction are perpendicular to each other. Alternatively, in some embodiments, the first guide groove 113 and the second guide grove 114 can be also disposed symmetrically in the front-rear direction shown in FIG. 1. In this case, the second direction is the same as the third direction. The embodiment is not limited thereto.

### Embodiment 2

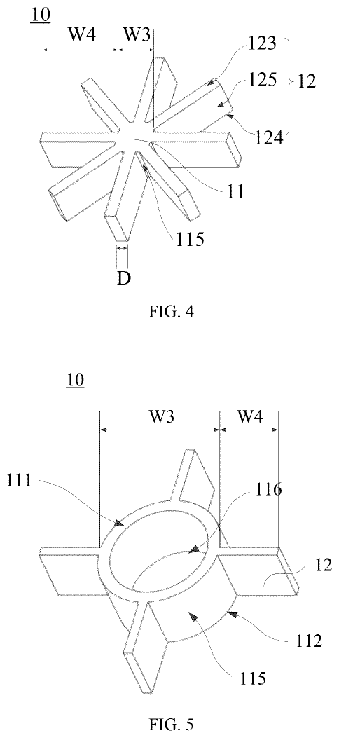

An embodiment 2 of the disclosure provides another micro bonding device 10, which is used to bond and connect two to-be-bonded electrodes. The micro bonding device 10 includes a main part 11 and multiple micro connectors 12. The multiple micro connectors 12 protrude from the main part 11, and are arranged at intervals. The multiple micro connectors 12 are configured to plug with the two to-be-bonded electrodes. Specifically, the two to-be-bonded electrodes can be a chip electrode of a micro LED chip and a substrate electrode on a display substrate corresponding to the chip electrode respectively. That is, the multiple micro connectors 12 are configured to plug with a chip electrode and a substrate electrode, to achieve bonding between the micro LED chip and the substrate. Specifically, as shown in FIG. 4, the main part 11 includes a first surface 111, a second surface 112 and a side surface 115. The first surface 111 and the second surface 112 are opposite in a first direction, and the side surface 115 is located between the first surface 111 and the second surface 112. The multiple micro connectors 12 are multiple blades respectively protruding from the side surface 115 and disposed around the main part 11, each of the multiple micro connectors 12 includes a first connector end 123 and a second connector end 124, and the first connector end 123 and the second connector end 124 are opposite in the first direction. The first connector end 123 is configured to plug with one of the two to-be-bonded electrodes, and the second connector end 124 is configured to plug with the other of the two to-be-bonded electrodes. As shown in FIG. 4, the main part 11 may be a columnar structure, and 8 blade-shaped micro connectors 12 are arranged around the main part 11. According to the orientation shown in FIG. 4, an upper end of each micro connector 12 is the first connector end 123, and a lower end of each micro connector 12 is the second connector end 124. For example, when the micro LED chip is bonded on the display substrate, the upper end of each micro connector 12 is plugged with the chip electrode, and the lower end of each micro connector 12 is plugged with the substrate electrode. In this way, when repairing the micro LED chip, the physical plugging of the micro bonding device 10 with the chip electrode and the substrate electrode replaces the heating welding of the solder, and there is no need to perform single-point heating on the repair position, and it will not affect the adjacent soldered chips.

In an embodiment, the main part 11 defines a third width dimension W3 along a second direction, and the second direction is perpendicular to the first direction. For example, the main part 11 is a columnar structure, and a diameter of the columnar structure is the third width dimension W3. When the main part 11 is solid columnar structure shown in FIG. 4, the third width dimension W3 is in a range of 100 nm to 1000 nm. A blade length W4 of each micro connector 12 protruding from the side surface 115 is in a range of 1 μm to 2 μm. An overall height (i.e., a distance between the first surface 111 and the second surface 112) of the micro bonding device 10 is in a range of 1 μm to 3 μm. A thickness D of each micro connector 12 is in a range of 100 nm to 1000 nm. The principle of repairing using the micro bonding device 10 provided in the embodiment is the same as that in the aforementioned embodiment 1. In the embodiment, the main part 11 is disposed as a microneedle structure, which plays a role of plugging. The multiple micro connectors 12 are disposed as micro blade structures, which can be plugged with the two to-be-bonded electrodes and also play a role in assisting flight alignment.

In another embodiment, the main part 11 is a hollow columnar structure. As shown in FIG. 5, the main part 11 defines a through hole 116 penetrating from the first surface 111 to the second surface 112. In the embodiment, the third width dimension W3 is in a range of 1 μm to 3 μm. The blade length W4 of each micro connector 12 protruding from the side surface 115 is in a range of 0.5 μm to 1 μm. The main part 11 with a wider dimension can ensure the stability of the overall structure of the micro bonding device 10. Moreover, the setting of the through hole 116 makes the main part 11 keep a thinner wall thickness, which is more conducive to plugging.

In an embodiment, each micro connector 12 includes a blade middle 125 located between the first connector end 123 and the second connector end 124, and thicknesses of the first connector end 123 and the second connector end 124 each are smaller than or equal to a thickness of the blade middle 125. The first connector end 123 and the second connector end 124 are thinner than the blade middle 125, which is more conducive to plugging.

Manufacturing of the micro bonding devices 10 provided in the aforementioned embodiment 1 and the embodiment 2 can be achieved through the following steps. A substrate layer is growth on the substrate, the substrate can be a glass substrate or a sapphire substrate, and the substrate layer can be a gallium nitride substrate layer. Photoresist is coated on the substrate layer. The substrate layer coated with the photoresist is exposed and developed according to the shape of the micro bonding device to form a corresponding pattern. A metal block of a corresponding shape is obtained by evaporation, metal removal, degumming and other processes.

### Embodiment 3

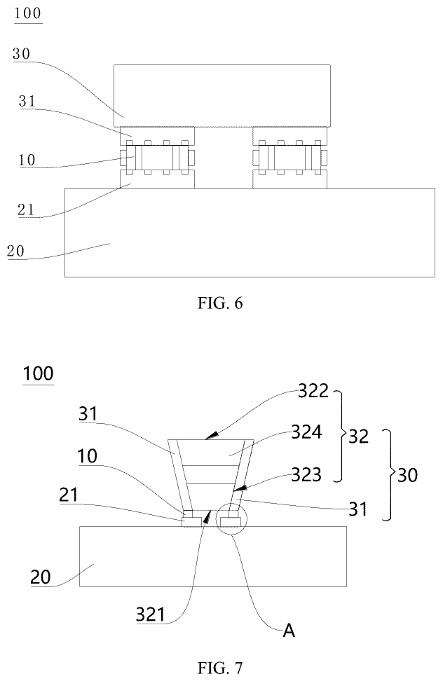

As shown in FIG. 6, an embodiment 3 of the disclosure provides a bonding backplane 100, including a substrate 20, a micro electronic device 30 and the micro bonding device 10 according to any one of the embodiment 1 and embodiment 2. The substrate 20 includes a first to-be-bonded electrode 21. The micro electronic device 30 includes a second to-be-bonded electrode 31. The micro bonding device 10 is disposed between the first to-be-bonded electrode 21 and the second to-be-bonded electrode 31. At least part of the multiple micro connectors 12 are plugged into the first to-be-bonded electrode 21, and at least part of the multiple micro connectors 12 are plugged into the second to-be-bonded electrode 31.

Specifically, the micro electronic device 30 may be a micro LED chip or another micro device with similar repair requirements. The substrate 20 may be a drive array substrate of the micro LED chip, and a drive circuit for driving the micro LED chip to emit light is also provided thereon. The second to-be-bonded electrode 31 of the micro electronic device 30 is bonded to the first to-be-bonded electrode 21 of the substrate 20 to achieve the electronic connection therebetween. For example, FIG. 6 illustrates a schematic structural diagram of the bonding backplane 100 using the micro bonding device 10 provided in the embodiment 1. The micro electronic device 30 includes two second to-be-bonded electrodes 31, the substrate 20 includes two first to-be-bonded electrodes 21 corresponding to the two second to-be-bonded electrodes 31, and a micro bonding device 10 is disposed between each pair of the second to-be-bonded electrode 31 and the first to-be-bonded electrode 21 to achieve the bonding connection. For example, when adopting the micro bonding device 10 in the embodiment 1, the multiple first microneedles 121 are plugged with the first to-be-bonded electrode 21, and the multiple second microneedles 122 are plugged with the second to-be-bonded electrode 31. Alternatively, when adopting the micro bonding device 10 in the embodiment 2, the first connector ends 123 of the multiple micro connectors 12 are plugged with the first to-be-bonded electrode 21, and the second connector ends 124 of the multiple micro connectors 12 are plugged with the second to-be-bonded electrode 31. In an embodiment, hardness of the multiple micro connectors 12 is greater than hardness of the first to-be-bonded electrode 21 and hardness of the second to-be-bonded electrode 31, which can achieve a better plugging and bonding effect.

As shown in FIG. 7, in some embodiments, the micro electronic device 30 includes a device body 32 and a second to-be-bonded electrode 31. The device body 32 has a bottom surface 321, a top surface 322 and a chip side surface 323. The bottom surface 321 and the top surface 322 are opposite in a stacking direction, and the chip side surface 323 is adjacent to the bottom surface 321 and the top surface 322. The device body 32 includes multiple semiconductor layers 324 stacked along the stacking direction. The second to-be-bonded electrode 31 is electrically connected to the device body 32, and is partially disposed on the chip side surface 323 of the device body 32.

As shown in FIG. 8, the micro bonding device 10 is disposed between the first to-be-bonded electrode 21 and the second to-be-bonded electrode 31. The micro bonding device 10 includes a main part 11 and multiple micro connectors 12, and the multiple micro connectors 12 protrude from the main part 11 and are arranged at intervals. At least part of the multiple micro connectors 12 are plugged with the first to-be-bonded electrode 21, and at least part of the multiple micro connectors 12 are plugged with the second to-be-bonded electrode 31, to make the first to-be-bonded electrode 21 and the second to-be-bonded electrode 31 bond with each other.

Specifically, the substrate 20 may be a drive array substrate of the micro LED chip, which is provided with a drive circuit for driving the micro LED chip to emit light. Specifically, the first to-be-bonded electrode 21 is electrically connected to the drive circuit. The micro electronic device 30 may be a micro LED chip or another micro device with the similar bonding and repairing requirements. The device body 32 may be a body structure of the micro LED chip, and the multiple semiconductor layers 324 included by the device body 32 may include a N-type semiconductor layer, a multiple quantum well (MQW) layer and a P-type semiconductor layer. The number of the N-type semiconductor layer, the MQW layer and the P-type semiconductor layer may be multiple. Certainly, the device body 32 may also include a reflection layer, an ohmic contact layer and an insulation layer other than the multiple semiconductor layers 324. The layers included in the device body 32 can be set with reference to the structure of a traditional micro LED chip. The bottom surface 321 and the top surface 322 are two opposite surfaces of the device body 32 in the stacking direction. The second to-be-bonded electrode 31 may be a N electrode connected to the N-type semiconductor layer of the device body 32, or may be a P electrode connected to the P-type semiconductor layer of the device body 32. Alternatively, both the N electrode and the P electrode are the second to-be-bonded electrode 31.

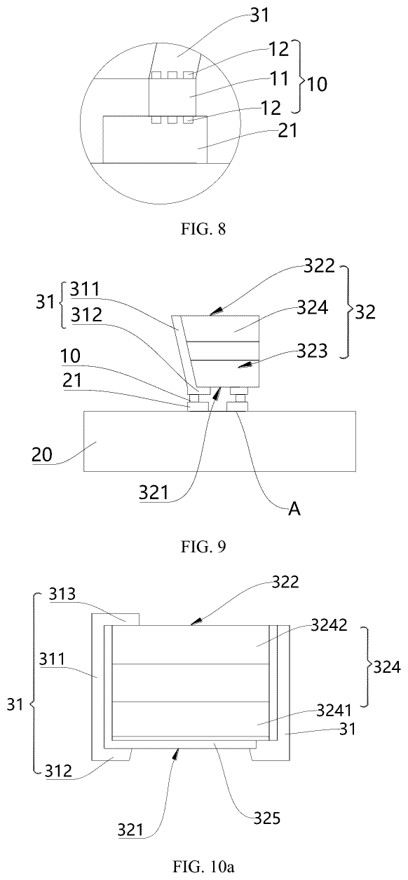

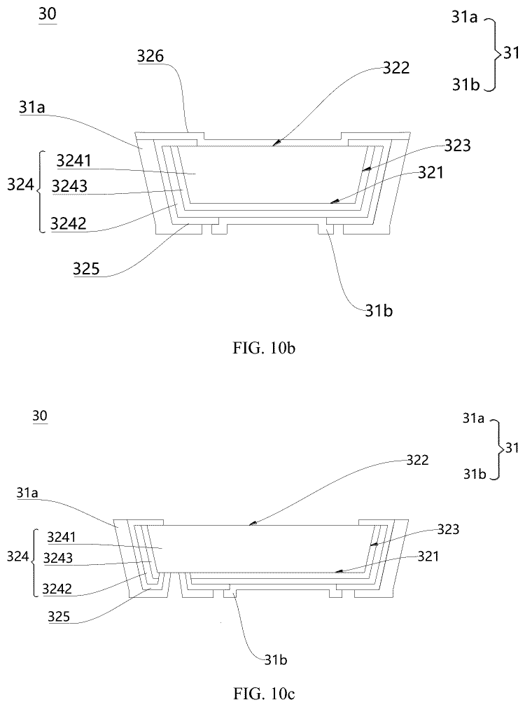

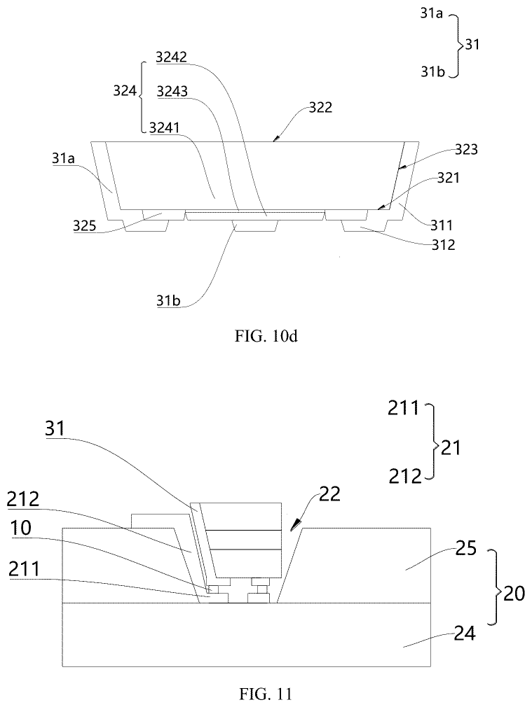

At least part of the second to-be-bonded electrode 31 is located on the chip side surface 323, that is, the second to-be-bonded electrode 31 may be all located on the chip side surface 323, may extend from the bottom surface 321 to the chip side surface 323, may extend from the top surface 322 to the chip side surface 323, and may extend from the top surface 322 to the chip side surface 323 and then to the bottom surface 321 (as shown in FIG. 10a). The N electrode and the P electrode are taken as examples, one of the N electrode and the P electrode is disposed on the chip side surface 323, the other is disposed on the bottom surface 321 (as shown in FIG. 9). When the N electrode and the P electrode are both the second to-be-bonded electrode 31, the N electrode and the P electrode can be disposed on two opposite chip side surfaces 323, can be also disposed on two adjacent chip side surfaces 323, which can increase the distance between the N electrode and the P electrode. One of the N electrode and the P electrode can be all disposed on the chip side surface 323, the other of the N electrode and the P electrode extends from the bottom surface 321 or the top surface 322 to the chip side surface 323. A part of the second to-be-bonded electrode 31 located on the chip side surface 323 can increase a coverage area of the electrode materials, reduce resistance, and reduce an area in contact with the first to-be-bonded electrode 21 during subsequent bonding. In some scenarios, the part of the second to-be-bonded electrode 31 located on the chip side surface 323 can be also used to connect multiple semiconductor layers of the same type (e.g., connect two N-type semiconductor layers).

It should be noted that a necessary insulation layer may be disposed between the second to-be-bonded electrode 31 and the chip side surface 323, so that the second to-be-bonded electrode 31 is electrically connected to a part of the multiple semiconductor layers 324, and is insulated from the other semiconductor layers 324. For example, the N electrode is only electrically connected to the N-type semiconductor layer, and is insulated from the P-type semiconductor layer and the MQW layer through the insulation layer.

During bonding or repairing of the micro electronic device 30, the lase-assisted transfer method and the like are used to transfer the micro bonding device 10 on the first to-be-bonded electrode 21, so that the micro bonding device 10 is plugged into the first to-be-bonded electrode 21 first. Then the micro electronic device 30 is transferred onto the micro bonding device 10 through the laser-assisted transfer method. During laser-assisted transferring, after being irritated by the laser, the adhesive material on the transfer carrier is vaporized to release the micro bonding device 10 or the micro electronic device 30, which can provide a certain flying speed, so that the micro bonding device 10 is plugged into the first to-be-bonded electrode 21, and the second to-be-bonded electrode 31 is plugged into the micro bonding device 10, so as to obtain the bonding backplane provided in the aforementioned embodiment of the disclosure. This plugging structure makes it unnecessary to use conductive adhesive connection or welding and other high-temperature bonding methods, so that the impact on other adjacent devices can be reduced during the bonding or repair process.

In some embodiments, as shown in FIG. 7, the second to-be-bonded electrode 31 includes a chip electrode side 311, and the chip electrode side 311 is disposed on the chip side surface 323. The micro bonding device 10 is plugged with an end of the chip electrode side 311 and the first to-be-bonded electrode 21 individually. Specifically, the chip electrode side 311 can be set as an inclined structure (as shown in FIG. 7) or a non-inclined structure according to the shape of the device body 32, the embodiment does not limit it.

In some embodiments, as shown in FIG. 9, the second to-be-bonded electrode 31 includes a chip electrode side 311 and a chip electrode bottom 312. The chip electrode side 311 is disposed on the chip side surface 323, and the chip electrode bottom 312 is disposed on the bottom surface 321, and is connected to the chip electrode side 311. The micro bonding device 10 is plugged with the chip electrode bottom 312 and the first to-be-bonded electrode 21 individually. The chip electrode bottom 312 can increase a contact area between the micro bonding device 10 and the second to-be-bonded electrode 31, and reduce the difficulty of plugging the micro bonding device 10 and the second to-be-bonded electrode 31, which makes the bonding more stable. The chip electrode side 311 can increase an overall area of the second to-be-bonded electrode 31, so as to obtain a better conductive transmission effect.

In some embodiments, as shown in FIG. 10a, the second to-be-bonded electrode 31 includes a chip electrode side 311 and a chip electrode top 313. The chip electrode side 311 is disposed on the chip side surface 323, and the chip electrode top 313 is disposed on the top surface 322. The multiple semiconductor layers 324 include a first semiconductor layer 3241 and a second semiconductor layer 3242. The second semiconductor layer 3242 is disposed between the first semiconductor layer 3241 and the top surface 322, and the chip electrode top 313 is electrically connected to the second semiconductor layer 3242, and is insulated from the first semiconductor layer 3241. The second to-be-bonded electrode 31 further includes a chip electrode bottom 312, and the chip electrode bottom 312 is connected to an end of the chip electrode side 311 facing away from the chip electrode top 313. The micro bonding device 10 is plugged with the chip electrode bottom 312 and the first to-be-bonded electrode 21 individually. Specifically, the first semiconductor layer 3241 can be a N-type semiconductor layer, thus the second semiconductor layer 3242 is a P-type semiconductor layer. Alternatively, the first semiconductor layer 3241 is a P-type semiconductor layer, thus the second semiconductor layer 3242 is a N-type semiconductor layer. The second to-be-bonded electrode 31 is insulated from the first semiconductor layer 3241 through the passivation layer 325. The second to-be-bonded electrode 31 is set as a structure which extends from the top surface 322 to the chip side surface 323, and finally extends to the bottom surface 321, and the micro bonding device 10 is combined, thus the bonding of some specific micro electronic devices 30 is more convenient to realize.

In some embodiments, the multiple semiconductor layers 324 include a first semiconductor layer 3241, an active layer 3243 and a second semiconductor layer 3242, and the first semiconductor layer 3241 has the bottom surface 321, the top surface 322 and the chip side surface 323. The active layer 3243 covers the bottom surface 321 and the chip side surface 323, and the second semiconductor layer 3242 covers the active layer 3243. The first semiconductor layer 3241 can be the N-type semiconductor layer, thus the second semiconductor layer 3242 is the P-type semiconductor layer. Alternatively, the first semiconductor layer 3241 is the P-type semiconductor layer, thus the second semiconductor layer 3242 is the N-type semiconductor layer. The active layer 3243 is the MQW layer. A first semiconductor layer 3241 with a hexahedral structure is taken as an example, the active layer 3243 covers five surfaces of the first semiconductor layer 3241 other than the top surface 322. The second semiconductor layer 3242 covers the active layer 3243 according to the same method of the active layer 3243.

In some embodiments, as shown in FIG. 10b, the device body 32 further includes a passivation layer 325, and the passivation layer 325 covers the second semiconductor layer 3242. The second to-be-bonded electrode 31 includes a first polar electrode 31a and a second polar electrode 31b. The second polar electrode 31b penetrates through the passivation layer 325 and is electrically connected to the second semiconductor layer 3242. The first polar electrode 31a is insulated from the second semiconductor layer 3242 by the passivation layer 325, and the first polar electrode 31a is electrically connected to the first semiconductor layer 3241. At least part of one of the first polar electrode 31a and the second polar electrode 31b is disposed on the chip side surface 323. A type of the first polar electrode 31a corresponds to a type of the first semiconductor layer 3241, and a type of the second polar electrode 31b corresponds to a type of the second semiconductor layer 3242. When the first semiconductor layer 3241 is the N-type semiconductor layer and the second semiconductor layer 3242 is the P-type semiconductor layer, the first polar electrode 31a is the N electrode and the second polar electrode 31b is the P electrode.

Specifically, the passivation layer 325 includes a bottom passivation layer and a side passivation layer, the bottom passivation layer corresponds to the bottom surface 321, and the side passivation layer corresponds to the chip side surface 323. The bottom passivation layer defines an opening for the second polar electrode 31b to pass through, so that the second polar electrode 31b can be disposed on a side of the bottom surface 321, and is connected to the second semiconductor layer 3242. A part of the first polar electrode 31a covers a side of the chip side surface 323, and a part of the first polar electrode 31a extends to a side of the bottom surface 321. The first polar electrode 31a is insulated from the second semiconductor layer 3242 by the passivation layer 325. The passivation layer 325 includes a top passivation layer corresponding to the top surface 322. As shown in FIG. 10b, the top passivation layer defines an opening, a transparent electrode 326 is disposed on the top surface 322, the transparent electrode 326 penetrates the top passivation layer, and is connected to the first semiconductor layer 3241, and the transparent electrode 326 extends to an end of the first polar electrode 31a proximate to the top surface 322, to connect with the first polar electrode 31a, so that the first polar electrode 31a is connected to the first semiconductor layer 3241. Referring to the structure shown in FIG. 10b, the micro electronic device 30 can bond parts of the first polar electrode 31a and the second polar electrode 31b disposed on the bottom surface 321 on the substrate 20 through the micro bonding device 10. The light emitted by the micro electronic device 30 can penetrate through transparent electrode 326, and exits from a side of the top surface 322 facing away from the bottom surface 321.

As shown in FIG. 10c, in some embodiments, the transparent electrode 326 may not be provided, and parts of the active layer 3243 and the second semiconductor layer 3242 located on the bottom surface 321 define a guide hole, the passivation layer 325 extends to a sidewall of the guide hole, and the first polar electrode 31a extends into the guide hole and is connected to the first semiconductor layer 3241, and the first polar electrode 31a is insulated from the active layer 3243 and the second semiconductor layer 3242 through the part of the passivation layer 325 extending to the sidewall of the guide hole.

In some other embodiments, as shown in FIG. 10d, the multiple semiconductor layers 324 include a first semiconductor layer 3241, an active layer 3243 and a second semiconductor layer 3242, and the first semiconductor layer 3241 has the bottom surface 321, the top surface 322 and the chip side surface 323. The active layer 3243 and the second semiconductor layer 3242 are stacked on the bottom surface 321 in that order. Areas of orthographic projections of the active layer 3243 and the second semiconductor layer 3242 on the bottom surface 321 are smaller than an area of the bottom surface 321. The second to-be-bonded electrode 31 includes a first polar electrode 31a and a second polar electrode 31b. The second polar electrode 31b is disposed on a side of the second semiconductor layer 3242 facing away from the active layer 3243, and is electrically connected to the second semiconductor layer 3242. At least part of the first polar electrode 31a is disposed on the chip side surface 323 and is electrically connected to first semiconductor layer 3241.

In some embodiments, as shown in FIG. 10d, the device body 32 further includes a passivation layer 325, and the passivation layer 325 is disposed on the bottom surface 321. The first polar electrode 31a includes a chip electrode side 311 and a chip electrode bottom 312. The chip electrode side 311 is disposed on the chip side surface 323, and the chip electrode bottom 312 is disposed on a side of the passivation layer 325 facing away from the bottom surface 321. The chip electrode bottom 312 and the second polar electrode 31b are bonded with the substrate 20 respectively through the micro bonding device 10.

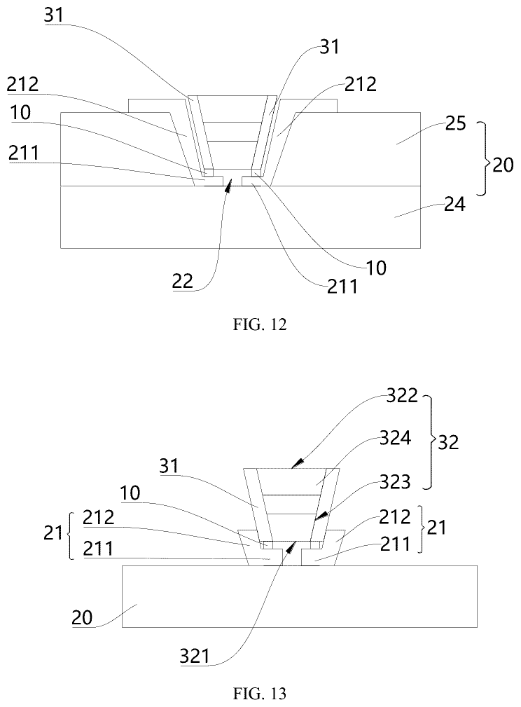

In some embodiments, as shown in FIG. 11 and FIG. 12, the substrate 20 defines a groove 22. The first to-be-bonded electrode 21 includes a substrate electrode bottom 211, and the substrate electrode bottom 211 is disposed on a bottom of the groove 22. The micro electronic device 30 is disposed in the groove 22. The micro bonding device 10 is plugged with the second to-be-bonded electrode 31 and the substrate electrode bottom 211 individually. Specifically, the substrate 20 includes a driving circuit board 24 and a pixel definition layer 25, and the pixel definition layer 25 is disposed on the driving circuit board 24. The driving circuit board 24 is provided with a driving circuit, and the first to-be-bonded electrode 21 is electrically connected to the driving circuit on the driving circuit board 24 through the substrate electrode bottom 211. The groove 22 is defined, so that the micro electronic device 30 can not only achieve stable bonding through the micro bonding device 10, but also be limited by embedding the micro electronic device 30 in the groove 22 to improve the bonding effect.

Specifically, the first to-be-bonded electrode 21 further includes a substrate electrode side 212, and the substrate electrode side 212 is disposed on a side wall of the groove 22, and is connected to the substrate electrode bottom 211. The second to-be-bonded electrode 31 includes a chip electrode side 311, and the chip electrode side 311 is disposed on the chip side surface 323, and is connected to the substrate electrode side 212. The substrate electrode side 212 (as shown in FIG. 11) can be disposed only corresponding to one of the N electrode and the P electrode of the micro electronic device 30 according to actual needs, or the substrate electrode side 212 (as shown in FIG. 12) is disposed corresponding to both the N electrode and the P electrode of the micro electronic device 30. The setting of the substrate electrode side 212 can increase the contact area between the first to-be-bonded electrode 21 and the second to-be-bonded electrode 31, so as to obtain better conductivity.

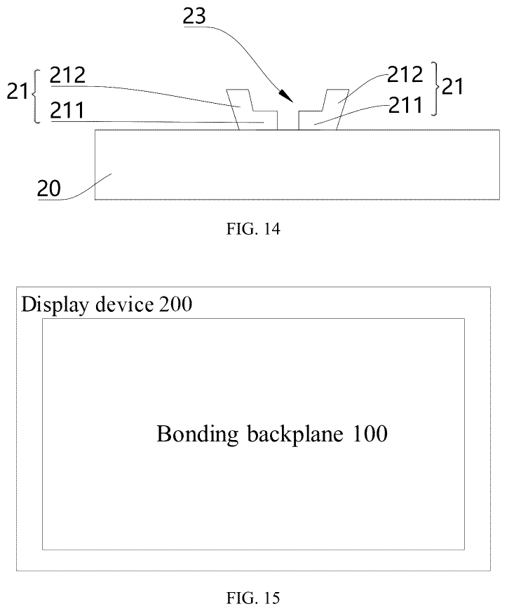

In some embodiments, as shown in FIG. 13 and FIG. 14, the first to-be-bonded electrode 21 includes a substrate electrode bottom 211 and a substrate electrode side 212. The substrate electrode bottom 211 is disposed on the substrate 20, and the substrate electrode side 212 extends along the substrate electrode bottom 211 in a direction facing away from the substrate 20. The micro bonding device 10 is plugged with the substrate electrode bottom 211 and the second to-be-bonded electrode 31 individually. The second to-be-bonded electrode 31 includes a chip electrode side 311, and the chip electrode side 311 is disposed on the chip side surface 323, and is connected to the substrate electrode side 212. In the embodiment, through forming the substrate electrode side 212 through the first to-be-bonded electrode 21 itself, the contact area between the first to-be-bonded electrode 21 and the second to-be-bonded electrode 31 is increased, while the manufacturing of the pixel definition layer 25 is saved, which reduces the costs.

Specifically, multiple second to-be-bonded electrodes 31 of the micro electronic device 30 correspond to multiple first to-be-bonded electrodes 21 one by one and are bonded to each other. As shown in FIG. 14, the substrate electrode sides 212 of the multiple first to-be-bonded electrodes 21 of a same micro electronic device 30 enclose together to define an accommodating groove 23, and the micro electronic device 30 is disposed in the accommodating groove 23. For example, there are two second to-be-bonded electrodes 31 (i.e., N electrode and P electrode, respectively) corresponding to one micro electronic device 30, thus one micro electronic device 30 corresponds to two first to-be-bonded electrodes 21. As shown in FIG. 13 and FIG. 14, the substrate electrode sides 212 of the two first to-be-bonded electrodes 21 are disposed opposite each other, so that the micro electronic device 30 can be disposed between the two substrate electrode sides 212. In this way, through the two substrate electrode sides 212, the contact area between the first to-be-bonded electrode 21 and the second to-be-bonded electrode 31 is increased, and the micro electronic device 30 is limited, so as to stably bond the micro electronic device 30 on the substrate 20. Moreover, there is no need for high-temperature heating such as conductive adhesive and solder, which can reduce the impact on adjacent devices during bonding or repair.

As shown in FIG. 15, an embodiment of the disclosure further provides a display device 200, including the bonding backplane according to any one the foregoing, and the micro electronic device 30 is a micro light emitting device.

The production cost and process difficulty of the bonding backplane 100 and the display device 200 repaired using the micro bonding device 10 provided in the above embodiments are greatly reduced.

The embodiment of the disclosure further provides display equipment, including the display device 200 according to the foregoing. The display equipment can be a mobile phone, a computer, a car display screen, or another terminal device with the display function. The display equipment has the same beneficial effect of the above bonding backplane 100, and it will not be repeated here.

The above is merely some of the embodiments of the disclosure and does not constitute any form of limitation to the disclosure. Although the disclosure has been disclosed as the embodiment as above, they are not intended to limit the disclosure. Any one of those skilled in the art can make some changes or amendments to equivalent embodiments of the technical contents disclosed above without departing from the scope of the technical solution of the disclosure. However, any simple amendment, equivalent change and amendment made to the above embodiments based on the technical essence of the disclosure without departing from the content of the technical solution of the disclosure still fall within the scope of the technical solution of the disclosure.

What is claimed is:

1. A micro bonding device, configured to bond and connect two to-be-bonded electrodes, wherein the micro bonding device comprises:
a main part;
multiple micro connectors, protruding from the main part; wherein the multiple micro connectors are arranged at intervals; and
wherein the multiple micro connectors are configured to plug with the two to-be-bonded electrodes.

2. The micro bonding device as claimed in claim 1, wherein the main part comprises a first surface and a second surface that are opposite in a first direction; the multiple micro connectors comprise multiple first microneedles protruding from the first surface and multiple second microneedles protruding from the second surface; and the multiple first microneedles are configured to plug with one of the two to-be-bonded electrodes, and the multiple second microneedles are configured to plug with the other of the two to-be-bonded electrodes.

3. The micro bonding device as claimed in claim 2, wherein the main part defines a first height dimension along the first direction and a first width dimension along a second direction; the second direction is perpendicular to the first direction; the first height dimension is in a range of 1 micron (μm) to 3 μm; the first width dimension is in a range of 1 μm to 5 μm; heights of the multiple first microneedles and the multiple second microneedles protruding from the main part are in a range of 100 nanometers (nm) to 1000 nm respectively; each of the multiple first microneedles and each of the multiple second microneedles each define a second width dimension along the second direction, and the second width dimension is in a range of 100 nm to 1000 nm.

4. The micro bonding device as claimed in claim 2, further comprising: a first flying wing and a second flying wing that are symmetrically disposed on two opposite sides of the main part in a second direction; wherein the second direction is perpendicular to the first direction; and the first flying wing and the second flying wing individually extend along the first direction.

5. The micro bonding device as claimed in claim 4, wherein the main part defines a first guide groove and a second guide groove that are symmetrically disposed along a third direction, and the third direction is perpendicular to the first direction; and the first guide groove and the second guide groove individually penetrate through the first surface and the second surface along the first direction.

6. The micro bonding device as claimed in claim 1, wherein the main part comprises a first surface, a second surface and a side surface, the first surface and the second surface are opposite in a first direction, and the side surface is located between the first surface and the second surface; the multiple micro connectors are multiple blades respectively protruding from the side surface and disposed around the main part, and each of the multiple micro connectors comprises a first connector end and a second connector end that are opposite in the first direction; and the first connector end is configured to plug with one of the two to-be-bonded electrodes, and the second connector end is configured to plug with the other of the two to-be-bonded electrodes.

7. The micro bonding device as claimed in claim 6, wherein the main part defines a third width dimension along a second direction; the second direction is perpendicular to the first direction; the third width dimension is in a range of 100 nm to 1000 nm; and a blade length of each of the multiple micro connectors protruding from the side surface is in a range of 1 μm to 2 μm.

8. The micro bonding device as claimed in claim 6, wherein the main part defines a through hole penetrating from the first surface to the second surface.

9. The micro bonding device as claimed in claim 8, wherein the main part defines a third width dimension along a second direction; the second direction is perpendicular to the first direction; the third width dimension is in a range of 1 μm to 3 μm; and a blade length of each of the multiple micro connectors protruding from the side surface is in a range of 0.5 μm to 1 μm.

10. The micro bonding device as claimed in claim 6, wherein each of the multiple micro connectors comprises a blade middle located between the first connector end and the second connector end, and thicknesses of the first connector end and the second connector end each are smaller than or equal to a thickness of the blade middle.

11. A bonding backplane, comprising:
a substrate, comprising a first to-be-bonded electrode;
a micro electronic device, comprising a second to-be-bonded electrode; and
the micro bonding device as claimed in claim 1, disposed between the first to-be-bonded electrode and the second to-be-bonded electrode; wherein at least part of the multiple micro connectors are plugged into the first to-be-bonded electrode, and at least part of the multiple micro connectors are plugged into the second to-be-bonded electrode.

12. The bonding backplane as claimed in claim 11, wherein hardness of the multiple micro connectors is greater than hardness of the first to-be-bonded electrode and hardness of the second to-be-bonded electrode.

13. The bonding backplane as claimed in claim 11, wherein the micro electronic device further comprises a device body, and the device body has a bottom surface, a top surface and a chip side surface; the bottom surface and the top surface are opposite in a stacking direction, and the chip side surface is adjacent to the bottom surface and the top surface; the device body comprises multiple semiconductor layers stacked along the stacking direction; and the second to-be-bonded electrode is electrically connected to the device body, and is partially disposed on the chip side surface of the device body.

14. The bonding backplane as claimed in claim 13, wherein the second to-be-bonded electrode comprises a chip electrode side disposed on the chip side surface; and the micro bonding device is plugged with an end of the chip electrode side and the first to-be-bonded electrode individually.

15. The bonding backplane as claimed in claim 13, wherein the second to-be-bonded electrode comprises a chip electrode side and a chip electrode bottom, the chip electrode side is disposed on the chip side surface, and the chip electrode bottom is disposed on the bottom surface, and is connected to the chip electrode side; and the micro bonding device is plugged with the chip electrode bottom and the first to-be-bonded electrode individually.

16. The bonding backplane as claimed in claim 13, wherein the second to-be-bonded electrode comprises a chip electrode side and a chip electrode top, the chip electrode side is disposed on the chip side surface, and the chip electrode top is disposed on the top surface; the multiple semiconductor layers comprise a first semiconductor layer and a second semiconductor layer, the second semiconductor layer is disposed between the first semiconductor layer and the top surface, and the chip electrode top is electrically connected to the second semiconductor layer, and is insulated from the first semiconductor layer; and the second to-be-bonded electrode further comprises a chip electrode bottom connected to an end of the chip electrode side facing away from the chip electrode top, and the micro bonding device is plugged with the chip electrode bottom and the first to-be-bonded electrode individually.

17. The bonding backplane as claimed in claim 13, wherein the substrate defines a groove, and the first to-be-bonded electrode comprises a substrate electrode bottom disposed on a bottom of the groove; the micro electronic device is disposed in the groove; and the micro bonding device is plugged with the second to-be-bonded electrode and the substrate electrode bottom individually.

18. The bonding backplane as claimed in claim 17, wherein the first to-be-bonded electrode further comprises a substrate electrode side disposed on a side wall of the groove, and the substrate electrode side is connected to the substrate electrode bottom; and the second to-be-bonded electrode comprises a chip electrode side disposed on the chip side surface, and the chip electrode side is connected to the substrate electrode side.

19. The bonding backplane as claimed in claim 13, wherein the first to-be-bonded electrode comprises a substrate electrode bottom and a substrate electrode side, the substrate electrode bottom is disposed on the substrate, and the substrate electrode side extends along the substrate electrode bottom in a direction facing away from the substrate; the micro bonding device is plugged with the substrate electrode bottom and the second to-be-bonded electrode individually; and the second to-be-bonded electrode comprises a chip electrode side disposed on the chip side surface, and the chip electrode side is connected to the substrate electrode side.

20. The bonding backplane as claimed in claim 19, wherein a number of the second to-be-bonded electrode is multiple, and a number of the first to-be-bonded electrode is multiple, and the multiple second to-be-bonded electrodes of the micro electronic device correspond to the multiple first to-be-bonded electrodes one by one and are bonded to each other; and the substrate electrode sides of the multiple first to-be-bonded electrodes of the micro electronic device enclose together to define an accommodating groove, and the micro electronic device is disposed in the accommodating groove.

21. The bonding backplane as claimed in claim 13, wherein the multiple semiconductor layers comprise a first semiconductor layer, an active layer and a second semiconductor layer, and the first semiconductor layer has the bottom surface, the top surface and the chip side surface; the active layer covers the bottom surface and the chip side surface; and the second semiconductor layer covers the active layer.

22. The bonding backplane as claimed in claim 21, wherein the device body further comprises a passivation layer covering the second semiconductor layer; the second to-be-bonded electrode comprises a first polar electrode and a second polar electrode; the second polar electrode penetrates through the passivation layer and is electrically connected to the second semiconductor layer; the first polar electrode is insulated from the second semiconductor layer by the passivation layer, and the first polar electrode is electrically connected to the first semiconductor layer; and at least part of one of the first polar electrode and the second polar electrode is disposed on the chip side surface.

23. The bonding backplane as claimed in claim 13, wherein the multiple semiconductor layers comprise a first semiconductor layer, an active layer and a second semiconductor layer, and the first semiconductor layer has the bottom surface, the top surface and the chip side surface; the active layer and the second semiconductor layer are stacked on the bottom surface in that order; areas of orthographic projections of the active layer and the second semiconductor layer on the bottom surface are smaller than an area of the bottom surface; the second to-be-bonded electrode comprises a first polar electrode and a second polar electrode; the second polar electrode is disposed on a side of the second semiconductor layer facing away from the active layer, and is electrically connected to the second semiconductor layer; and at least part of the first polar electrode is disposed on the chip side surface and is electrically connected to first semiconductor layer.

24. A display device, comprising:
the bonding backplane as claimed in claim 11, wherein the micro electronic device is a micro light-emitting device.
